(19) United States
(12) Patent Application Publication
(10) Pub. No.: US 2012/0092410 A1
(43) Pub. Date: Apr. 19, 2012

(54) SOLVENT RESISTANT PRINTHEAD

(76) Inventors: DAVID GRAHAM, Lexington, KY (US); Sean Weaver, Union, KY (US)

(21) Appl. No.: 13/249,979

(22) Filed: Sep. 30, 2011

Related U.S. Application Data
(60) Provisional application No. 61/394,474, filed on Oct. 19, 2010.

(51) Int. Cl. B41J 2/015; C23C 16/44; B32B 3/00; B32B 9/04; B32B 19/00

(52) U.S. Cl. 347/20; 428/411.1; 428/446; 428/702; 428/447; 428/336; 427/255.28

(57) ABSTRACT

A solvent resistant printhead having a barrier deposited and intercalating into the various polymeric materials on the printhead is disclosed. The deposition process may be performed at the various level of production depending on what material or surface requires protection from the solvent. The barrier may include a base coating and an outer coating. The base coating may include an intercalate layer deposited on the printhead and intercalating into the various polymeric materials and a tie layer deposited on the intercalate layer. The outer coating may be a self-assembled monolayer deposited on the base coating.

### CROSS REFERENCES TO RELATED APPLICATIONS

This patent application is related to and claims priority to U.S. Provisional Patent Application Ser. No. 61/394,474 entitled “Solvent Resistant Printhead” which was filed on Oct. 19, 2010.

### STATEMENT REGARDING FEDERALLY SPONSORED RESEARCH OR DEVELOPMENT

None.

### REFERENCE TO SEQUENTIAL LISTING, ETC.

None.

### BACKGROUND

1. Technical Field

The present disclosure relates to micro-fluid ejection devices. More particularly, it relates to inkjet printheads using solvent based inks.

2. Description of the Related Art

The art of printing images with micro-fluid technology is relatively well-known. In the field of micro-fluid ejection devices, current nozzle plate materials and the upilex/phenolic ablated materials have been engineered to be compatible with aqueous based inks. The aqueous based inks are suitable for thermal inkjet due to water nucleation kinetics and pumping effectiveness. Aqueous based inks are traditionally ejected onto porous media such has cellulose pulp paper or photopaper. The aqueous base ink surface tensions are low enough to establish wetting onto the paper and this wetting enables penetration into the porous media and provides good coverage yielding good print quality. Unfortunately, use of the aqueous based inks on other substrates, specifically low surface energy, non-porous media such as PVC, PET, ceramics, PP, coated papers, and other non-porous media used in the industrial market, has shown adhesion issues due to the inability of the aqueous based inks to wet the surface and penetrate into the substrate. For printing on non-porous media, solvent-based inks are being used.

Solvents that are typically used in solvent-based inks generally have lower surface tension compared to water and will wet lower surface energy surfaces/substrates. Solvent-based inks, however, may not be compatible with the ablated or nozzle plate materials, encap, diebond, TAB circuits, covercoat and other organic materials used in printheads designed for aqueous based inks. The solvents in solvent-based inks have lower surface tensions and increased solubility with organic materials allowing them to diffuse and swell the various polymeric materials of the printhead. Diffusion of the solvent and moisture into the material may lead to an accelerated corrosion failure, premature loss of adhesion, and print quality defects.

Accordingly, a need exists to provide an improved solution for printheads using solvent-based inks.

### SUMMARY OF THE INVENTION

The above-mentioned and other problems become solved with a solvent-resistant printhead. The printhead having a polymeric material may include a barrier to protect the printhead against corrosion and loss of adhesion that may be caused by exposure to solvent-based inks.

In one example embodiment, the barrier may include a base coating and an outer coating. The base coating may include an intercalate layer and a tie layer. The intercalate layer may be deposited on the printhead and may intercalate into the various polymeric materials of the printhead. The tie layer may be deposited on and may chemically bond with the intercalate layer. The intercalate layer and the tie layer may be oxide layers. The intercalate layer may be an aluminum oxide layer while the tie layer may be a silicon dioxide layer. The outer coating may be a self-assembled monolayer deposited on the base coating.

The barrier may encapsulate all the polymeric based materials and free surfaces on the printhead, leading to improve solvent resistance. Once the barrier is deposited on the printhead assembly, solvent and moisture may be prevented from reaching or penetrating the polymeric materials thus providing corrosion protection and improved solvent compatibility to the printhead assembly. The intercalation of the intercalate layer into the various polymeric materials of the printhead may enable better adhesion of the barrier to the printhead assembly.

### BRIEF DESCRIPTION OF THE DRAWINGS

A more thorough understanding of the example embodiments may be had from the consideration of the following detailed description taken in conjunction with the accompanying drawings.

FIG. 1 is a diagrammatic view of an example embodiment of an advanced surface modification employing the barrier in the present disclosure.

FIG. 2 is a detailed view of the base coating of FIGS. 1.

FIG. 3 is a flowchart depicting a method of forming the barrier of FIG. 1.

### DETAILED DESCRIPTION

It is to be understood that the invention is not limited in its application to the details of construction and the arrangement of components set forth in the following description or illustrated in the drawings. The invention is capable of other embodiments and of being practiced or of being carried out in various ways. Also, it is to be understood that the phraseology and terminology used herein is for the purpose of description and should not be regarded as limiting. The use herein of “including,” “comprising,” or “having” and variations thereof is meant to encompass the items listed thereafter and equivalents thereof as well as additional items. Unless limited otherwise, the terms “connected,” “coupled,” and “mounted,” and variations thereof herein are used broadly and encompass direct and indirect connections, couplings, and mountings. In addition, the terms “connected” and “coupled” and variations thereof are not restricted to physical or mechanical connections or couplings.

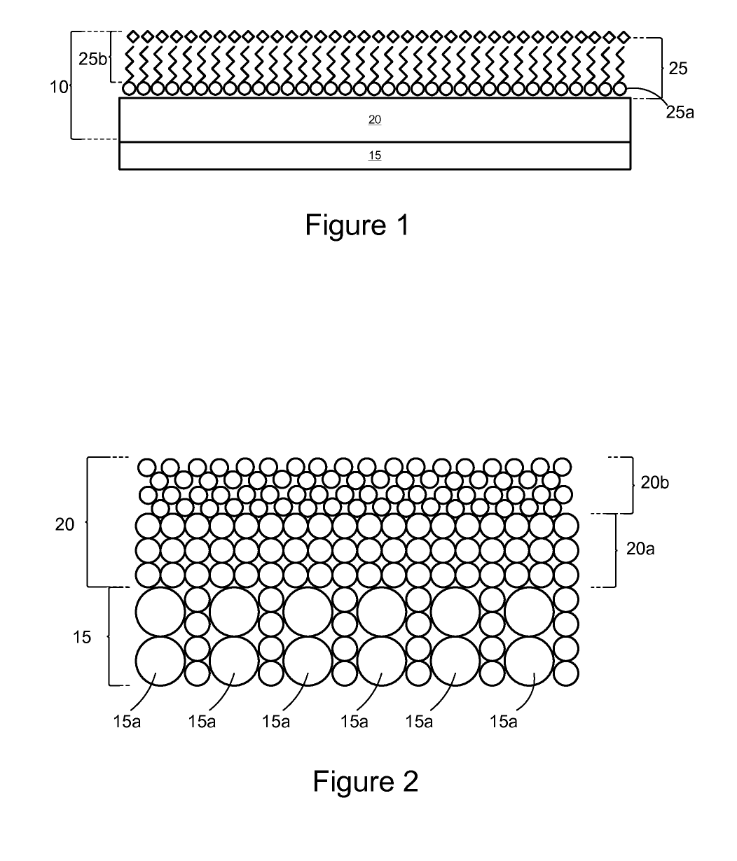

Referring now to the drawings and more particularly to FIG. 1, there is shown one example embodiment of the barrier 10 of the present disclosure. The barrier 10 may consist of a base coating 20 deposited on the substrate 15 and an outer coating 25, such as a self-assembled monolayer, deposited on the base coating 20. The substrate 15 in the present disclosure may include various polymeric materials used in making the printhead. The barrier 10 may have a thickness range of about 100 Angstrom to about 400 Angstrom and may encapsulate all free surfaces of a finished printhead assembly (not shown) to protect the printhead assembly from various solvents and moisture which may cause corrosion and loss of adhesion between the bather 10 and the printhead assembly by preventing solvent from reaching or penetrating the polymeric materials. The self-assembled monolayer 25 is a one molecule thick layer of material that chemically bonds to the base coating 20 in an ordered way as a result of physical or chemical forces during the deposition process and may be created by the chemisorption of hydrophilic head groups 25a onto the base coating 20 from either the vapor or liquid phase followed by a slow two-dimensional organization of hydrophobic tail groups 25b. The hydrophilic head groups 25a may assemble together on the base coating 20, while the hydrophobic tail groups 25b may assemble far from the base coating 20. The self-assembled monolayer 25 may be deposited by physical vapor deposition process and a covalent bonding may occur between the self-assembled monolayer 25 and the base coating 20 during deposition. The deposition of the self-assembled monolayer 25 on the base coating 20 may provide sufficient hydrophobic character to the barrier 10 and may cause the ink (not shown) to be less wetting. The contact angle of water for the self-assembled monolayer 25 is from about 90 degrees to about 120 degrees.

FIG. 2 is a detailed view of the base coating 20 of FIG. 1 being deposited on a polymeric material 15a of the substrate 15. The base coating 20 may include an intercalate layer 20a and a tie layer 20b. The intercalate layer 20a may enable adhesion of the barrier 10 to the printhead assembly. To achieve a better adhesion to the printhead assembly, the intercalate layer 20a may be deposited such that the intercalate layer 20a intercalates into the various polymeric materials 15a of the substrate 15. In one example embodiment, the intercalate layer 20a may be an Al₂O₃ layer deposited by atomic layer deposition. The use of an Al₂O₃ layer as an example intercalate layer 20a may not be considered limiting as other layers with different chemical compositions may be used as an intercalate layer 20a for the present disclosure.

Atomic layer deposition is a process of applying thin films to various substrates with atomic scale precision similar in chemistry to chemical vapor deposition, except that in an atomic layer deposition, an atomic layer deposition reaction may break a chemical vapor deposition reaction into two half-reactions and may keep the precursor materials separate during the reaction. Atomic layer deposition film growth may be self-limited and may be based on surface reactions, which may make achieving atomic scale deposition control possible. By keeping the precursors separate throughout the coating process, atomic layer thickness control of film grown may be obtained as fine as atomic/molecular scale per monolayer.

The atomic layer deposition process may enable the intercalate layer 20a to intercalate into the various polymeric materials 15a with atomic scale precision and uniformity. Once the intercalate layer 20a is formed, chemical vapor deposition may be employed to deposit the tie layer 20b on the intercalate layer 20b. The tie layer 20b may be deposited on the intercalate layer 20a such that the intercalate layer 20a and the tie layer 20b chemically bonds together and sufficient hydroxyl groups are provided for the deposition of the self-assembled monolayer 25. In one example embodiment, the tie layer 20b may be a SiO2 layer deposited by chemical vapor deposition process on the intercalate layer 20a. The use of a SiO2 layer as an example tie layer 20b may not be considered limiting as other layers with different chemical compositions may be used as a tie layer 20b for the present disclosure.

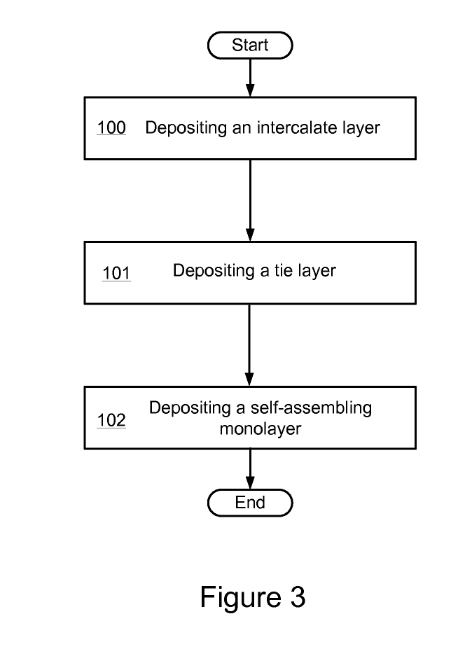

FIG. 3 is a flowchart depicting one example method of forming the barrier 10 of FIG. 1. At block 100, an intercalate layer 20a may be deposited on the substrate 15 such that the intercalate layer 20a intercalates into the polymeric material 15a of the substrate 15. In one example embodiment, atomic layer deposition may be used to deposit the intercalate layer 20.

At block 101, the tie layer 20b is deposited on the intercalate layer 20a. The tie layer 20b may be deposited by chemical vapor deposition process. During the deposition, the tie layer 20b may chemically bond with the intercalate layer 20a forming the base coating 20. The deposition of the tie layer 20b may also provide the hydroxyl groups (not shown) for the deposition of the self-assembled monolayer 25.

At block 102, the self-assembled monolayer 25 may be deposited on the base coating 20, particularly, the tie layer 20b. In one example embodiment, the self-assembled monolayer 25 may be an octadecyltrichlorosilane self-assembled monolayer. In another example embodiment, the self-assembled monolayer 25 may be a perfluorodecyl-trichlorosilane self-assembled monolayer. In yet another example embodiment, undecenyltrichlorosilane self-assembled monolayer may be used. Other chemicals having alkyltrichlorosilanes may be used as self-assembled monolayer 25 in the present disclosure.

The foregoing description of several methods and an embodiment of the invention has been presented for purposes of illustration. It is not intended to be exhaustive or to limit the invention to the precise steps and/or forms disclosed, and obviously many modifications and variations are possible in light of the above teaching. It is intended that the scope of the invention be defined by the claims appended hereto.

What is claimed is:

1. A micro-fluid ejection device, comprising:
a printhead having a polymeric material;
a base coating having:
an intercalate layer deposited on the printhead and intercalating into the polymeric material; and
a tie layer deposited on the intercalate layer, the tie layer bonding with the intercalate layer; and
an outer coating deposited on the base coating, the outer coating being a self-assembled monolayer.

2. The micro-fluid ejection device of claim 1, wherein the intercalate layer comprises aluminum oxide.

3. The micro-fluid ejection device of claim 1, wherein the tie layer comprises silicon dioxide.

4. The micro-fluid ejection device of claim 1, wherein the self-assembled monolayer is an octadecyltrichlorosilane self-assembled monolayer.

5. The micro-fluid ejection device of claim 1, wherein the self-assembled monolayer is a perfluorodecyltrichlorosilane self-assembled monolayer.

6. The micro-fluid ejection device of claim 1, wherein the self-assembled monolayer is an undecenyltrichlorosilane self-assembled monolayer.

7. The micro-fluid ejection device of claim 1, wherein the base coating and the self-assembled monolayer have a total thickness of about 100 Angstroms to about 400 Angstroms.

8. The micro-fluid ejection device of claim 1, wherein the self-assembled monolayer has a water contact angle of about 90 degrees to about 120 degrees.

9. A barrier disposed on a printhead having a polymeric material, comprising:
a base coating including,
an intercalate layer deposited on the printhead and intercalating into the polymeric material; and
a tie layer deposited on the intercalate layer, the tie layer bonding with the intercalate layer; and
an outer coating deposited on the base coating, the outer coating being a self-assembled monolayer.

10. The barrier of claim 9, wherein the intercalate layer comprises aluminum oxide.

11. The barrier of claim 9, wherein the tie layer comprises silicon dioxide.

12. The barrier of claim 9, wherein the self-assembled monolayer is an octadecyl-trichlorosilane self-assembled monolayer.

13. The barrier of claim 9, wherein the self-assembled monolayer is a perfluorodecyltrichlorosilane self-assembled monolayer.

14. The barrier of claim 9, wherein the self-assembled monolayer is an undecenyltrichlorosilane self-assembled monolayer.

15. The barrier of claim 9, wherein the barrier has a thickness of about 100 to about 400 Angstroms.

16. The barrier of claim 9, wherein the self-assembled monolayer has a water contact angle of about 90 to about 120 degrees.

17. A method of forming a bather on a printhead, comprising:
depositing an intercalate layer of a base coating by atomic layer deposition, the intercalate layer intercalating into a polymeric material of the printhead;
depositing a tie layer of the base coating on the intercalate layer by chemical vapor deposition, the tie layer bonding with the intercalate layer; and
depositing a self-assembled monolayer of an outer coating on the base coating.

18. The method of claim 17, wherein the depositing the self-assembled monolayer includes depositing octadecyltrichlorosilane by vapor deposition.

19. The method of claim 17, wherein the depositing the self-assembled monolayer includes depositing perfluorodecyltrichlorosilane by vapor deposition.

20. The method of claim 17, wherein the depositing the self-assembled monolayer includes depositing undecenyltrichlorosilane by vapor deposition.
